(19) United States
(12) Patent Application Publication
(10) Pub. No.: US 2014/0061658 A1
(43) Pub. Date: Mar. 6, 2014

(54) High Electron Mobility Transistor and Manufacturing Method Thereof

(71) Applicants: Chien-Wei Chiu, Beigang Township (TW); Tsung-Yi Huang, Hsinchu City (TW)

(72) Inventors: Chien-Wei Chiu, Beigang Township (TW); Tsung-Yi Huang, Hsinchu City (TW)

(73) Assignee: Richtek Technology Corporation

(21) Appl. No.: 13/603,392

(22) Filed: Sep. 4, 2012

(51) Int. Cl. H01L 29/778; H01L 21/338

(52) U.S. Cl. 257/76; 438/172; 257/E29.252; 257/E21.403

(57) ABSTRACT

The present invention discloses an enhanced mode high electron mobility transistor (HEMT) which includes: a P-type gallium nitride (GaN) layer; a barrier layer, which is formed on and connected to the GaN layer; a dielectric layer, which is formed on and connected to the GaN layer, wherein the barrier layer does not overlap at least part of the dielectric layer; a gate, which is formed on the dielectric layer for receiving a gate voltage; and a source and a drain, which are formed at two sides of the gate on the GaN layer respectively; wherein a two dimensional electron gas (2DEG) is formed at a junction of the GaN layer and the barrier layer which does not include a portion of the junction below the gate, and the 2DEG does not electrically connect the source to the drain when there is no voltage applied to the gate.

### BACKGROUND OF THE INVENTION

1. Field of Invention

The present invention relates to a high electron mobility transistor (HEMT) and a manufacturing method thereof; particularly, it relates to an enhanced mode HEMT and manufacturing method thereof.

2. Description of Related Art

FIGS. 1A and 1B show a schematic cross-section view and a band diagram of a prior art high electron mobility transistor (HEMT) 100. As shown in FIG. 1A, a gallium nitride (GaN) layer 12 is formed on a substrate 11, and an isolation region 13 is formed in the GaN layer 12. The isolation region 13 for example is formed by a shallow trench isolation (STI) process or a local oxidation of silicon (LOCOS) process, the former being shown in the figure. The HEMT 100 further includes an aluminum gallium nitride (AlGaN) layer 14, a gate 15, a source 16, and a drain 17 besides the GaN layer 12 and the isolation region 13. A two dimensional electron gas (2DEG) 18 is formed at the junction between the GaN layer 12 and the AlGaN layer 14, and the 2DEG 18 is electrically connected both to the source 16 and the drain 17. As shown in FIG. 1B, The Fermi level Efs of the GaN layer 12 and the Fermi level Efb of the AlGaN layer 14 are at the same level. The conduction levels, i.e., the lowest level of the conduction band, Ecs of the GaN layer 12 and Ecb of the AlGaN layer 14, and the valence levels, i.e., the highest level of the valence band, Evs of the GaN layer 12 and Evb of the AlGaN layer 14, are bended at the junction of the GaN layer 12 and the AlGaN layer 14, such that the electrons are trapped in the electron well 18a. These trapped electrons can eliminate Coulomb scattering to increase the electron mobility in the 2DEG 18, such that the operation speed of the HEMT 100 is faster than a conventional semiconductor device at ON state.

However, the HEMT 100 is a depletion mode device, i.e., the gate voltage of the HEMT 100 is negative during normal operations. In practical applications, it is not convenient to adopt and operate a depletion mode device, especially in high frequency applications. A positive gate voltage of an HEMT during normal operations can decrease the complexity of the circuitry and the manufacturing cost.

In view of above, to overcome the drawbacks in the prior art, the present invention proposes an enhanced mode HEMT and a manufacturing method thereof which provide a lower manufacturing cost, and the HEMT may have a broader application range.

### SUMMARY OF THE INVENTION

A first objective of the present invention is to provide an HEMT.

A second objective of the present invention is to provide a manufacturing method of an HEMT.

To achieve the objectives mentioned above, from one perspective, the present invention provides an HEMT, including: a P-type gallium nitride (GaN) layer; a barrier layer, which is formed on the GaN layer, and is connected to the GaN layer; a dielectric layer, which is formed on the GaN layer, and is connected to the GaN layer, wherein the barrier layer does not overlap at least part of the dielectric layer; a gate, which is formed on the dielectric layer for receiving a gate voltage; and a source and a drain, which are formed at two sides of the gate respectively; wherein a two dimensional electron gas (2DEG) is formed in at least a portion of a junction between the GaN layer and the barrier layer but not below the gate, and the 2DEG does not electrically connect the source to the drain when there is no voltage applied to the gate, such that the HEMT is an enhanced mode device.

From another perspective, the present invention provides a manufacturing method of a high electron mobility transistor (HEMT), including: providing a P-type gallium nitride (GaN) layer; forming a barrier layer on and connected to the GaN layer; forming a dielectric layer on and connected to the GaN layer, wherein the barrier layer does not overlap at least part of the dielectric layer; forming a gate on the dielectric layer for receiving a gate voltage; and forming a source and a drain at two sides of the gate respectively; wherein a two dimensional electron gas (2DEG) is formed in at least a portion of a junction between the GaN layer and the barrier layer but not below the gate, and the 2DEG does not electrically connect the source to the drain when there is no voltage applied to the gate, such that the HEMI is an enhanced mode device.

In one preferable embodiment, concentration of electron carriers in the 2DEG is higher than concentration of hole carriers in the GaN layer.

In another preferable embodiment, the dielectric layer has a dielectric constant not less than 3.9.

In yet another preferable embodiment, the barrier layer includes aluminum gallium nitride (AlGaN).

In yet another preferable embodiment, the dielectric layer has a length not less than a length of the gate in lateral direction from cross-section view.

The objectives, technical details, features, and effects of the present invention will be better understood with regard to the detailed description of the embodiments below.

### BRIEF DESCRIPTION OF THE DRAWINGS

FIGS. 1A and 1B show a schematic cross-section view and a band diagram of a conventional high electron mobility transistor (HEMT) 100.

FIG. 2 shows a first embodiment of the present invention.

FIGS. 3A-3D show a second embodiment of the present invention.

### DESCRIPTION OF THE PREFERRED EMBODIMENTS

The drawings as referred to throughout the description of the present invention are for illustration only, to show the interrelations between the regions and the process steps, but not drawn according to actual scale.

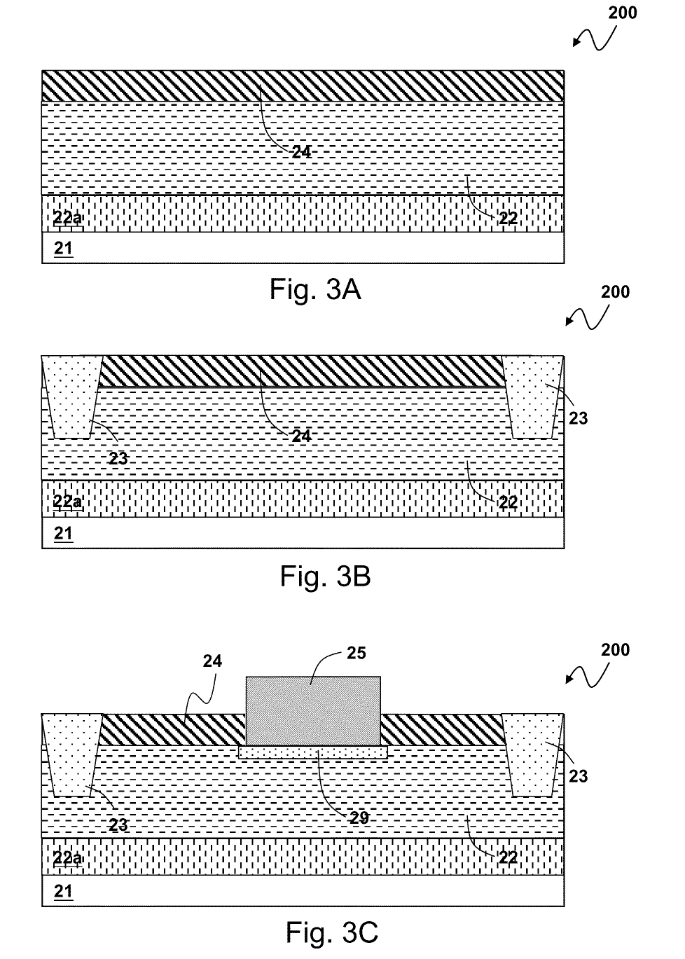

Please refer to FIG. 2 for a first embodiment according to the present invention. As shown in FIG. 2, a high electron mobility transistor (HEMT) 200 is formed on a substrate 21, and the substrate 21 is for example but not limited to a silicon substrate, a silicon carbide substrate, or a sapphire substrate. A buffer layer 22a is formed on the substrate 21 by for example but not limited to an epitaxial growth process. Next, a P-type gallium nitride (GaN) layer 22 is formed on the buffer layer 22a by for example but not limited to an epitaxial growth process. The buffer layer 22a is for example but not limited to a silicon layer. Besides, the HEMT 200 further includes a barrier layer 24, a gate 25, a source 26, a drain 27, and a dielectric layer 29.

The barrier layer 24 is for example but not limited to an aluminum gallium nitride (AlGaN) layer, which is formed on the GaN layer 22, and is connected to the GaN layer 22. The dielectric layer 29 is for example but not limited to an aluminum oxide (Al2O3) layer, which is formed on the GaN layer 22, and is connected to the GaN layer 22, wherein the barrier layer 24 does not overlap at least part of the dielectric layer 29. The gate 25 is formed on the dielectric layer 29 for receiving a gate voltage to turn ON or OFF the HEMT 200. The source 26 and the drain 27 are formed at two sides of the gate 25 on the GaN layer 22 respectively. A two dimensional electron gas (2DEG) 28 is formed in at least a portion of a junction between the GaN layer 22 and the barrier layer 24 but not below the gate 25, and the 2DEG 28 is electrically separately connected to the source 26 and the drain 27 when the HEMT is not conducting, that is, the 2DEG 28 does not electrically connect the source 26 to the drain 27 when there is no voltage applied to the gate, such that the HEMT is an enhanced mode device.. The HEMT 200 further includes for example but not limited to an isolation region 23, which may be formed by the STI process or the LOCOS process, the former being shown in the figure, or formed by an ion implantation process implanting N-type impurities into the substrate 21.

In a preferable embodiment, the gate 25 and the dielectric layer 29 are defined by for example but not limited to a same etching process. The etching process removes part of the GaN layer 22 with a predetermined depth, such that the dielectric layer 29 may be formed on the GaN layer 22 and has a substantially same size and shape with the gate 25 from top view (not shown). The dielectric layer 29 has a length not less than a length of the gate 25 in lateral direction from the cross-section view of FIG. 2, such that the 2DEG 28 is not directly electrically connected to the gate 25. In a preferable embodiment, the concentration of electron carriers in the 2DEG 28 is higher than the concentration of hole carriers in the GaN layer 22, such that the gate voltage for turning ON the HEMT 200 is positive. The HEMT 200 with a positive operation voltage has wider application range. The dielectric layer preferably has a dielectric constant not less than 3.9, i.e., not less than the dielectric constant of silicon dioxide, such that the HEMT 200 has a lower leakage current and enhanced electronic characteristics.

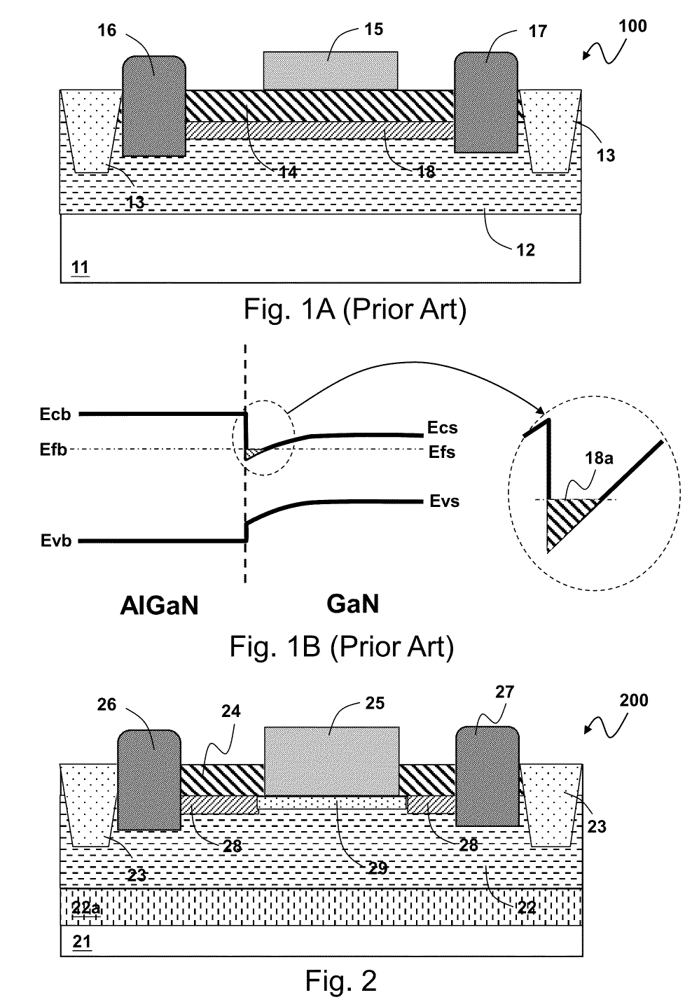

This embodiment is different from the prior art in that, in this embodiment, the dielectric layer 29 is formed between the gate 25 and the GaN layer 22 to disconnect the 2DEG 28, such that the HEMI 200 shown in FIG. 2 is not a depletion mode device as the conventional HEMI 100 as shown in FIG. 1A, but becomes an enhanced mode device, by a relatively simple process with flexibility in process modification.

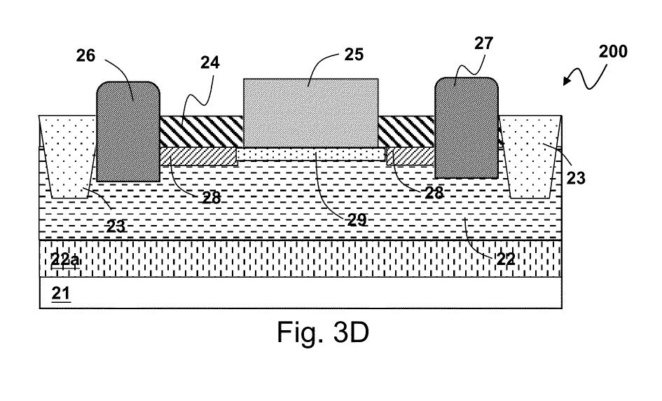

FIGS. 3A-3D are a second embodiment of the present invention, which show schematic cross-section views of a manufacturing method of the HEMI 200. As shown in FIG. 3A, first, the substrate 21 is provided, which is for example but not limited to the silicon substrate, the silicon carbide substrate, or the sapphire substrate. Next, the buffer layer 22a is formed on the substrate 21 by for example but not limited to the epitaxial process, wherein the buffer layer 22a is for example but not limited to the silicon layer. Next, the P-type GaN layer 22 is formed on the buffer layer 22a by for example but not limited to an epitaxial process. Next, the barrier layer 24 is formed on and connected to the GaN layer 22, wherein the barrier layer 24 is for example but not limited to the AlGaN layer.

Next, as shown in FIG. 3B, the isolation region 23 is formed, which may be formed by for example the STI process as shown in the figure, the LOCOS process, or the ion implantation process which implants N-type impurities in the semiconductor layer 22.

Next, as shown in FIG. 3C, the dielectric layer 29 is formed on and connected to the barrier layer 24, wherein the barrier layer 24 does not overlap at least part of the dielectric layer 29. Both the dielectric layer 29 and the barrier layer 24 have substantial portions which are directly connected to the GaN layer 22. The gate 25 and the dielectric layer 29 cover for example but not limited to a substantially same region on the GaN layer 22, such that the gate voltage can determine whether the portion of the 2DEG 28 below the gate is formed or not. The dielectric layer 29 has a length not less than a length of the gate 25 in lateral direction from cross-section view FIG. 3C to avoid inducing a leakage current through the gate 25 and the 2DEG 28. The gate is made of conductive material for example but not limited to a Schottky metal or a ohmic metal such as titanium, chromium, nickel, tungsten or an alloy thereof.

Next, as shown in FIG. 3D, the source 26 and the drain 27 are formed at two sides of the gate 25 respectively, on the GaN layer 22 of the HEMT 200 by for example but not limited to a same process. The source 26 and drain 27 include for example but not limited to titanium, aluminum, nickel, or gold, etc.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, other process steps or structures which do not affect the primary characteristics of the device, such as a passivation layer, etc., can be added. In view of the foregoing, the spirit of the present invention should cover all such and other modifications and variations, which should be interpreted to fall within the scope of the following claims and their equivalents.

What is claimed is:

1. A high electron mobility transistor (HEMT), comprising:
a P-type gallium nitride (GaN) layer;
a barrier layer, which is formed on the GaN layer, and is connected to the GaN layer;
a dielectric layer, which is formed on the GaN layer, and is connected to the GaN layer, wherein the barrier layer does not overlap at least part of the dielectric layer;
a gate, which is formed on the dielectric layer for receiving a gate voltage; and
a source and a drain, which are formed at two sides of the gate respectively;
wherein a two dimensional electron gas (2DEG) is formed in at least a portion of a junction between the GaN layer and the barrier layer but not below the gate, and the 2DEG does not electrically connect the source to the drain when there is no voltage applied to the gate, such that the HEMT is an enhanced mode device.

2. The HEMT of claim 1, wherein concentration of electron carriers in the 2DEG is higher than concentration of hole carriers in the GaN layer.

3. The HEMT of claim 1, wherein the dielectric layer has a dielectric constant not less than 3.9.

4. The HEMT of claim 1, wherein the barrier layer includes aluminum gallium nitride (AlGaN).

5. The HEMT of claim 1, wherein the dielectric layer has a length not less than a length of the gate in lateral direction from cross-section view.

6. A manufacturing method of a high electron mobility transistor (HEMT), comprising:
providing a P-type gallium nitride (GaN) layer;
forming a barrier layer on and connected to the GaN layer;
forming a dielectric layer on and connected to the GaN layer, wherein the barrier layer does not overlap at least part of the dielectric layer ;
forming a gate on the dielectric layer for receiving a gate voltage; and
forming a source and a drain at two sides of the gate respectively;
wherein a two dimensional electron gas (2DEG) is formed in at least a portion of a junction between the GaN layer and the barrier layer but not below the gate, and the 2DEG does not electrically connect the source to the drain when there is no voltage applied to the gate, such that the HEMT is an enhanced mode device.

7. The manufacturing method of claim 6, wherein concentration of electron carriers in the 2DEG is higher than concentration of hole carriers in the GaN layer.

8. The manufacturing method of claim 6, wherein the dielectric layer has a dielectric constant not less than 3.9.

9. The manufacturing method of claim 6, wherein the barrier layer includes aluminum gallium nitride (AlGaN).

10. The manufacturing method of claim 6, wherein the dielectric layer has a length not less than a length of the gate in lateral direction from cross-section view.
